(19) United States
(12) Patent Application Publication
(10) Pub. No.: US 2026/0362630 A1
(43) Pub. Date: Nov. 12, 2026

(54) ELECTRONIC DEVICE

(71) Applicant: Micas Networks Inc., SAN JOSE, CA (US)

(72) Inventors: Wei LIU, SAN JOSE, CA (US); Guohong LAI, SAN JOSE, CA (US)

(73) Assignee: Micas Networks Inc., SAN JOSE, CA (US)

(21) Appl. No.: 19/723,991

(22) Filed: Jun. 29, 2026

Related U.S. Application Data
(63) Continuation of application No. PCT/CN2025/117223, filed on Aug. 27, 2025.

(30) Foreign Application Priority Data
Dec. 30, 2024 (CN) 202411964331.7

(51) Int. Cl. H05K 7/20

(52) U.S. Cl. CPC H05K 7/20145; H05K 7/2039

(57) ABSTRACT

This application discloses an electronic device. The electronic device includes: a cavity; a heat dissipation air duct, disposed in the cavity and allowing an airflow to pass through to take away heat in the cavity; a first heat source, disposed in the cavity; a third heat source, disposed in the cavity, where a temperature specification of the third heat source is lower than a temperature specification of the first heat source; a first heat dissipation assembly, located in the heat dissipation air duct and in thermal contact with the first heat source; and a third heat dissipation assembly, located in the heat dissipation air duct and in thermal contact with the third heat source, where the third heat dissipation assembly is isolated from the first heat dissipation assembly, and is located upstream of an airflow direction of the airflow relative to the first heat dissipation assembly.

### CROSS-REFERENCE TO RELATED APPLICATIONS

This application is a continuation of International Application No. PCT/CN2025/117223, filed on 27. Aug., 2025, which claims priority to Chinese Patent Application No. 202411964331.7, filed with the China National Intellectual Property Administration on Dec. 30, 2024 and entitled “ELECTRONIC DEVICE”, both of which are incorporated herein by reference in their entireties.

### TECHNICAL FIELD

This application relates to the technical field of heat dissipation for devices, and in particular, to an electronic device.

### BACKGROUND

For an electronic device including a plurality of co-packaged heat sources, due to limited packaging space, heat dissipation of the electronic device is faced with a great challenge. Co-packaged optics (Co-Packaged Optics, CPO) is used as an example for description. CPO refers to co-packaging a switching chip and an optical engine on a single package substrate to form a chip-module co-package structure. CPO can greatly shorten a signal transmission distance, and has lower power consumption, more complete signals, and a higher transmission rate.

### SUMMARY

An embodiment of this application provides an electronic device. The electronic device includes: a cavity; a heat dissipation air duct, disposed in the cavity and allowing an airflow to pass through to take away heat in the cavity; a first heat source, disposed in the cavity; a third heat source, disposed in the cavity, where a temperature specification of the third heat source is lower than a temperature specification of the first heat source; a first heat dissipation assembly, located in the heat dissipation air duct and in thermal contact with the first heat source; and a third heat dissipation assembly, located in the heat dissipation air duct and in thermal contact with the third heat source, where the third heat dissipation assembly is isolated from the first heat dissipation assembly, and the third heat dissipation assembly is located upstream of an airflow direction of the airflow relative to the first heat dissipation assembly.

In the foregoing embodiment, heat sources with different temperature specifications are all provided with corresponding heat dissipation assemblies. A heat dissipation assembly of a heat source with a lower temperature specification is disposed upstream of the airflow direction, and a heat dissipation assembly of a heat source with a higher temperature specification is disposed downstream of the airflow. In addition, the two heat dissipation assemblies are independent of each other, thereby meeting heat dissipation requirements of the heat sources with different temperature specifications, achieving hierarchical heat dissipation management for the different heat sources, and reducing thermal crosstalk between the heat sources with different temperature specifications.

In an embodiment, the first heat dissipation assembly includes a first heat sink, and the third heat dissipation assembly includes a third heat sink, where along a gravity direction, a height of a top surface of the third heat sink relative to a bottom plate of the cavity is lower than a height of a top surface of the first heat sink relative to the bottom plate of the cavity.

In an embodiment, the first heat sink includes a plurality of first heat dissipation fins; and/or the third heat sink includes a plurality of third heat dissipation fins.

In an embodiment, the first heat dissipation assembly further includes a first substrate, where the first substrate is disposed between the first heat source and the first heat sink and is in thermal contact with the first heat source and the first heat sink respectively.

In an embodiment, the first substrate is also in thermal contact with the first heat source and the first heat sink respectively.

In an embodiment, the third heat dissipation assembly further includes a third substrate, where the third substrate is disposed between the third heat source and the third heat sink and is in thermal contact with the third heat source and the third heat sink respectively.

In an embodiment, the third heat dissipation assembly further includes a third heat-conducting member, where the third heat-conducting member is disposed between the third substrate and the third heat sink and is in thermal contact with the third substrate and the third heat sink respectively.

In an embodiment, a circuit board is disposed in the cavity, and the first heat source and the third heat source are fixedly disposed on the circuit board.

In an embodiment, orthographic projections of the first heat sink and the third heat sink on the circuit board do not overlap.

In an embodiment, the electronic device further includes a second heat source disposed in the cavity and a second heat dissipation assembly in thermal contact with the second heat source, where the second heat dissipation assembly is disposed in the heat dissipation air duct and located between the first heat dissipation assembly and the third heat dissipation assembly in the airflow direction, a temperature specification of the second heat source is lower than the temperature specification of the first heat source and higher than the temperature specification of the third heat source, and the second heat dissipation assembly is isolated from the first heat dissipation assembly and the third heat dissipation assembly respectively.

In an embodiment, the second heat dissipation assembly further includes a second heat sink, and the third heat dissipation assembly further includes a third substrate and a third heat sink, where the third substrate is disposed between the third heat source and the third heat sink and is in thermal contact with the third heat source and the third heat sink respectively, and is in contact with the second heat source and the second heat sink respectively.

In an embodiment, the second heat dissipation assembly further includes a second heat sink and a second heat dissipation substrate, where the second substrate is disposed between the second heat source and the second heat sink and is in thermal contact with the second heat source and the second heat sink respectively.

In an embodiment, a distance between the second heat source and the first heat source and a distance between the second heat source and the third heat source are less than or equal to a first preset value.

In an embodiment, the first heat dissipation assembly includes a first heat sink, the second heat dissipation assembly includes a second heat sink, and the third heat dissipation assembly includes a third heat sink, where orthographic projections of the first heat sink, the second heat sink, and the third heat sink on a circuit board on which the first heat source is packaged do not overlap.

In an embodiment, a height of the third heat sink in a gravity direction is greater than a height of the second heat sink in the gravity direction or a height of the first heat sink in the gravity direction.

In an embodiment, the first heat dissipation assembly includes a first heat sink, the second heat dissipation assembly includes a second heat sink, and the third heat dissipation assembly includes a third heat sink, where a width of the third heat sink in a width direction is less than or equal to a width of the first heat sink in the width direction.

In an embodiment, a width of the second heat sink in the width direction is greater than the width of the first heat sink in the width direction and/or the width of the third heat sink in the width direction.

### BRIEF DESCRIPTION OF DRAWINGS

To describe the technical solutions in embodiments of this application more clearly, the following briefly describes the accompanying drawings required for describing the embodiments. Clearly, the accompanying drawings in the following description show merely some embodiments of this application, and a person of ordinary skill in the art may still derive other drawings from these accompanying drawings without creative efforts.

FIG. 1 is a schematic diagram of a structure of an electronic device according to an embodiment of this application.

FIG. 2 is a schematic diagram of a structure of an electronic device according to an embodiment of this application.

FIG. 3 is a schematic diagram of a structure of a heat dissipation assembly according to an embodiment of this application.

FIG. 4 is a schematic diagram of a structure of a heat dissipation assembly according to another embodiment of this application.

FIG. 5 is a schematic diagram of a structure of a heat dissipation assembly according to still another embodiment of this application.

FIG. 6 is a schematic diagram of a structure of an electronic device according to an embodiment of this application.

FIG. 7 is a schematic diagram of a structure of an electronic device according to an embodiment of this application.

FIG. 8 is a top view of heat dissipation fins of different heat sinks according to an embodiment of this application.

FIG. 9 is a top view of heat dissipation fins of different heat sinks according to an embodiment of this application.

FIG. 10 is a top view of heat dissipation fins of different heat sinks according to an embodiment of this application.

FIG. 11 is a top view of heat dissipation fins of different heat sinks according to an embodiment of this application.

Reference numerals: 100. cavity; 110. bottom plate; 120. top plate; 130. side plate; 200. heat source; 210. first heat source; 211. first heating element; 220. second heat source; 221. second heating element; 230. third heat source; 231. third heating element; 300. heat dissipation assembly; 310. heat sink; 320. substrate; 330. heat-conducting member; 400. circuit board; 500. heat dissipation air duct; 300a. first heat dissipation assembly; 310a. first heat sink; 320a. first substrate; 330a. first heat-conducting member; 300b. second heat dissipation assembly; 310b. second heat sink; 320b. second substrate; 300c. third heat dissipation assembly; 310c. third heat sink; 320c. third substrate; 330c. third heat-conducting member; 600. connecting member; 610. first fastener; 620. second fastener;
01. chamber.

### DESCRIPTION OF EMBODIMENTS

The following clearly and thoroughly describes the technical solutions in embodiments of this application with reference to the accompanying drawings in embodiments of this application. Clearly, the described embodiments are only some rather than all of embodiments of this application. All other embodiments obtained by a person of ordinary skill in the art based on embodiments of this application without creative efforts shall fall within the protection scope of this application.

The terms “first” and “second” are merely for the purpose of description, and shall not be understood as an indication or implication of relative importance or an implicit indication of a quantity of indicated technical features. Therefore, a feature defined by “first” or “second” may explicitly or implicitly include one or more features. In the description of this application, “a plurality of” means at least two unless otherwise stated.

The terms “at least one (item)”, “at least one of”, and the like in the specification and claims of this application refer to any one, any two, or a combination of two or more of objects included therein. For example, at least one (item) of a, b, or c may indicate: “a”, “b”, “c”, “a and b”, “a and c”, “b and c”, or “a, b, and c”, where a, b, and c may be singular or plural. Similarly, “at least two (items)” refers to two or more, and its meaning is similar to that of “at least one (item)”.

In embodiments of this application, directional terms such as “upper”, “lower”, “transverse”, “longitudinal”, “horizontal”, and “vertical” may include but are not limited to those defined relative to orientations in which components are schematically placed in the accompanying drawings. It should be understood that the directional terms may be relative concepts. The directional terms are used for relative description and clarification, and may vary accordingly depending on changes of the orientations in which the components are placed in the accompanying drawings.

Unless otherwise defined in the context, the term “connection” in the specification and claims of this application may mean that one element is directly connected to another element, or may mean that one element is connected to another element through an intermediate element.

For an electronic device including a plurality of co-packaged heat sources, due to limited packaging space, heat dissipation of the electronic device is faced with a great challenge. Co-packaged optics (Co-packaged optics, CPO) is used as an example for description. CPO refers to co-assembling a switching chip and an optical engine on a same package substrate (for example, a slot) to form a chip-module co-package structure. CPO can greatly shorten a signal transmission distance, and has lower power consumption, more complete signals, and a higher transmission rate. However, because the switching chip is integrated in close proximity with an optical module, a related heat sink in direct contact with the switching chip can hardly provide effective heat dissipation for the optical module simultaneously. In addition, a plurality of chips are densely arranged in CPO, and temperature specifications of different chips and temperature specifications of the chips and optical modules are different. Constrained by limited packaging space, related heat dissipation apparatuses are mostly integrated heat sinks, which can hardly provide effective heat dissipation for a plurality of heat sources and cannot provide differentiated heat dissipation solutions for heat sources with different temperature specifications. Moreover, thermal crosstalk may occur between the optical module and the switching chip.

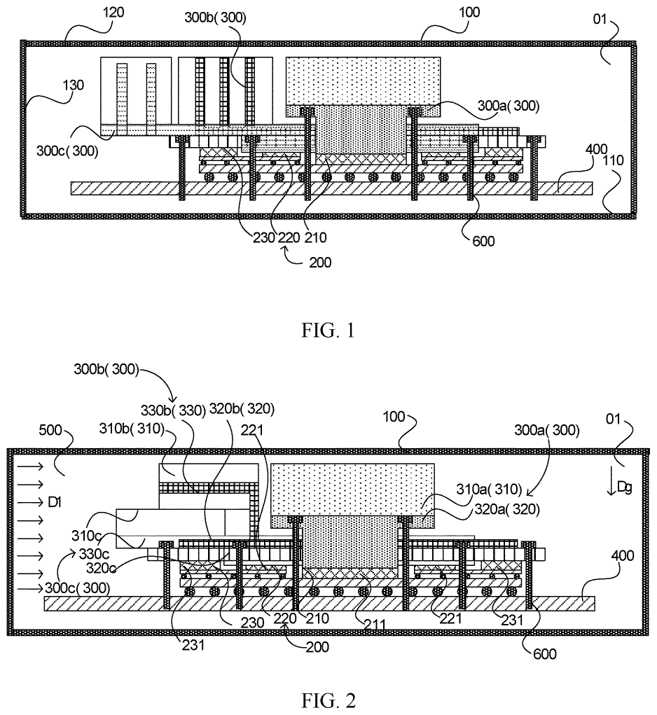

An embodiment of this application provides an electronic device. FIG. 1 is a schematic diagram of a structure of an electronic device according to an embodiment of this application. With reference to FIG. 1, the electronic device includes a cavity 100. At least two heat sources 200 with different temperature specifications and at least two heat dissipation assemblies 300 are disposed in the cavity 100. The heat dissipation assemblies 300 are in a one-to-one correspondence with the heat sources 200 and are in thermal contact with the corresponding heat sources 200. The heat dissipation assemblies 300 corresponding to the heat sources 200 with different temperature specifications are isolated from each other, so that the corresponding heat dissipation assemblies 300 are independent of each other. The isolation may be physical isolation, that is, there is a gap between the two heat dissipation assemblies; or the isolation may be thermal isolation achieved through a thermal insulator to reduce or avoid thermal crosstalk between the heat sources 200 with different temperature specifications.

It may be understood that a quantity of heat sources 200 with different temperature specifications in the electronic device may be two, three, or more. For example, the at least two heat sources 200 include a first heat source 210 and a third heat source 230, and a temperature specification of the first heat source 210 is higher than a temperature specification of the third heat source 230.

Further, a second heat source 220 may be disposed between the first heat source 210 and the third heat source 230, and a temperature specification of the second heat source 220 is higher than the temperature specification of the third heat source 230 and lower than the temperature specification of the first heat source 210.

The following description is provided by using an example in which the at least two heat sources 200 with different temperature specifications include three heat sources 200. The three heat sources 200 with different temperature specifications include the first heat source 210, the second heat source 220, and the third heat source 230. The temperature specification of the first heat source 210 is higher than the temperature specification of the second heat source 220, and the temperature specification of the second heat source 220 is higher than the temperature specification of the third heat source 230. A first heat dissipation assembly 300a is in thermal contact with the first heat source 210, a second heat dissipation assembly 300b is in thermal contact with the second heat source 220, and a third heat dissipation assembly 300c is in thermal contact with the third heat source 230.

The temperature specification refers to a temperature range that a heat source 200 can provide during normal operation, and this range depends on the type of the heat source 200 and a design purpose of the heat source 200. A heat source 200 with a lower temperature specification needs to operate under a lower temperature condition to maintain a good operating state.

It may be understood that the heat sources 200 with different temperature specifications are all provided with corresponding heat dissipation assemblies 300. The heat dissipation assemblies 300 may use different heat dissipation strategies based on operating conditions and power consumption of the corresponding heat sources 200, thereby providing tailored heat dissipation solutions for the heat sources 200 with different temperature specifications. Operating states of the heat dissipation assemblies 300 may also be adjusted based on different operating conditions of the heat sources 200. In this way, hierarchical heat dissipation management is achieved for different heat sources 200, and an energy-saving effect is also achieved.

The electronic device may be a CPO device, a near-packaged optics (Near-packaged Optics, NPO) device, a switch, or the like. As shown in FIG. 1, the electronic device is the CPO, and the CPO includes a switching chip and an optical module (or referred to as an optical engine), where the switching chip is the first heat source 210, and the optical engine may be the third heat source 230. A temperature specification of the switching chip may be less than or equal to 105 °C, and a temperature specification of the optical module may be less than or equal to 85 °C. The switching chip may include a plurality of chips, and the plurality of chips are closely arranged in the cavity 100.

With continued reference to FIG. 1, the electronic device includes a bottom plate 110, a top plate 120, and a plurality of side plates 130. The bottom plate 110, the top plate 120, and the side plates 130 enclose a chamber 01. The switching chip and the optical module are disposed in the chamber 01. For example, a quantity of the side plates 130 may be four, three, two, or one.

FIG. 2 is a schematic diagram of a structure of the electronic device according to an embodiment of this application. With reference to FIG. 2, the heat dissipation assembly 300 includes a heat sink 310. Optionally, the heat sink 310 may include at least one of a liquid cold plate, a heat dissipation fin, or a heat pipe. For example, the at least two heat sources 200 with different temperature specifications in FIG. 2 include the first heat source 210, the second heat source 220, and the third heat source 230. Correspondingly, the first heat dissipation assembly 300a includes a first heat sink 310a, the second heat dissipation assembly 300b includes a second heat sink 310b, and the third heat dissipation assembly 300c includes a third heat sink 310c.

Along a gravity direction Dg, a temperature specification of a heat source 200 corresponding to a heat sink 310 located below is lower than a temperature specification of a heat source 200 corresponding to a heat sink 310 located above. For example, the temperature specification of the third heat source 230 is lower than the temperature specification of the second heat source 220, and the third heat sink 310c is located below the second heat sink 310b. Because a density of hot air is less than that of cold air, the hot air may naturally rise, and the cold air may sink. The third heat sink 310c corresponding to the third heat source 230 with a lower temperature specification is located below, and the second heat sink 310b corresponding to the second heat source 220 with a higher temperature specification is located above. In this way, a natural convection effect can be enhanced, and heat dissipation efficiency can be improved. Moreover, this helps form a more distinct temperature stratification, thereby reducing thermal crosstalk between different heat sources 200 and improving a heat dissipation effect for each heat source 200. The electronic device in this application can reduce an operating temperature of the heat source 200 and surrounding components of the heat source 200 through more effective heat dissipation, thereby reducing thermal stress and extending a service life of the electronic device.

FIG. 3 is a schematic diagram of a structure of a heat dissipation assembly according to an embodiment of this application. With reference to FIG. 2 and FIG. 3 together, the heat dissipation assembly 300 further includes a substrate 320. The substrate 320 and the heat source 200 are stacked, and thermal contact between the heat sink 310 and the heat source 200 is achieved through the substrate 320. The substrate 320 has high thermal conductivity. The substrate 320 may be made from an aluminum plate, a copper plate, a vapor chamber (Vapor Chamber, VC) heat spreader, or other composite materials with high thermal conductivity. When the material for making the substrate 320 is a composite material, the substrate 320 may be an aluminum substrate embedded with heat pipes, a VC welded heat pipe, a three-dimensional (3-Dimensional Vapor Chamber, 3DVC), or the like.

It may be understood that a shape and size of the substrate 320 are not limited in this application, and may be set based on an actual requirement.

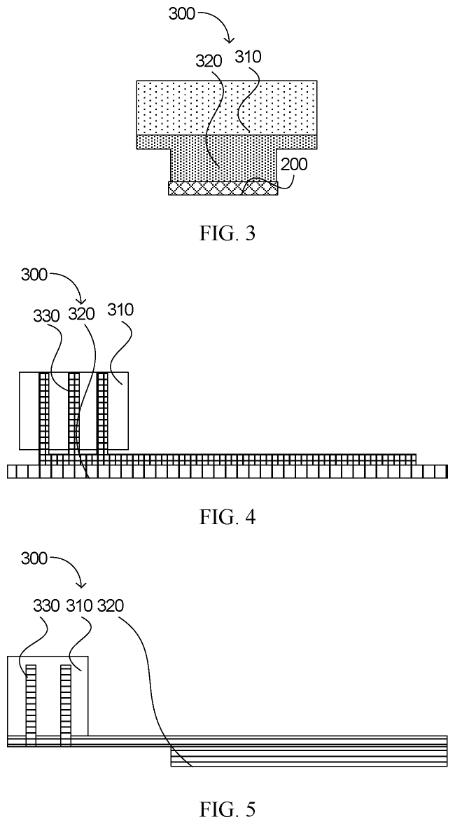

FIG. 4 is a schematic diagram of a structure of a heat dissipation assembly according to another embodiment of this application. FIG. 5 is a schematic diagram of a structure of a heat dissipation assembly according to still another embodiment of this application. With reference to FIG. 2, FIG. 4, and FIG. 5 together, the heat dissipation assembly 300 further includes a heat-conducting member 330. The substrate 320 and the heat sink 310 are connected through the heat-conducting member 330. The heat-conducting member 330 may be a heat pipe, a thermal pad, a thermal block, or the like. A material for making the heat-conducting member 330 may be a material with high thermal conductivity, such as graphite, metal, or an interface material.

Optionally, the heat-conducting member 330 is a flexible heat-conducting member 330, and may be flexibly arranged based on space and heat dissipation requirements. For example, for a heat source 200 with a lower temperature specification, a corresponding heat sink 310 may be moved, through the heat-conducting member 330, away from the substrate 320 to an upstream side of an airflow, so that the heat sink 310 corresponding to the heat source 200 with the lower temperature specification is first in contact with a cold airflow, thereby obtaining an optimal heat dissipation condition. Conversely, for a heat source 200 with a higher temperature specification, if the heat source 200 is located downstream of the cold airflow, a corresponding heat sink 310 may be directly disposed on one side of the heat source 200. If the heat source 200 is not located downstream of the cold airflow, the corresponding heat sink 310 may be expanded, through the heat-conducting member 330, away from the substrate 320 to a downstream side of the airflow to save energy.

With continued reference to FIG. 2 to FIG. 5, the first heat dissipation assembly 300a may include a first substrate 320a and a first heat sink 310a disposed on the first substrate 320a. The temperature specification of the first heat source 210 is the highest, and the first heat sink 310a may be disposed on a surface of the first substrate 320a facing away from the first heat source 210. In addition, the temperature specification of the third heat source 230 is the lowest, the third heat dissipation assembly 300c may include a third substrate 320c, a third heat sink 310c, and a third heat-conducting member 330c, and the third heat-conducting member 330c extends from the third substrate 320c toward the upstream side of the airflow, so that the third heat sink 310c is located upstream of the airflow, and the third heat sink 310c is first in contact with the cold airflow, thereby obtaining an optimal heat dissipation condition. The second heat dissipation assembly 300b may include a second substrate 320b, a second heat sink 310b, and a second heat-conducting member 330b. The second heat-conducting member 330b extends upward from the second substrate 320b, so that the second heat sink 310b is located above the third heat sink 310c and located upstream of the first heat sink 310a in the airflow. In this way, the second heat sink 310b can be preferentially in contact with the cold airflow, and a natural convection effect between the second heat sink 310b and the third heat sink 310c can be enhanced.

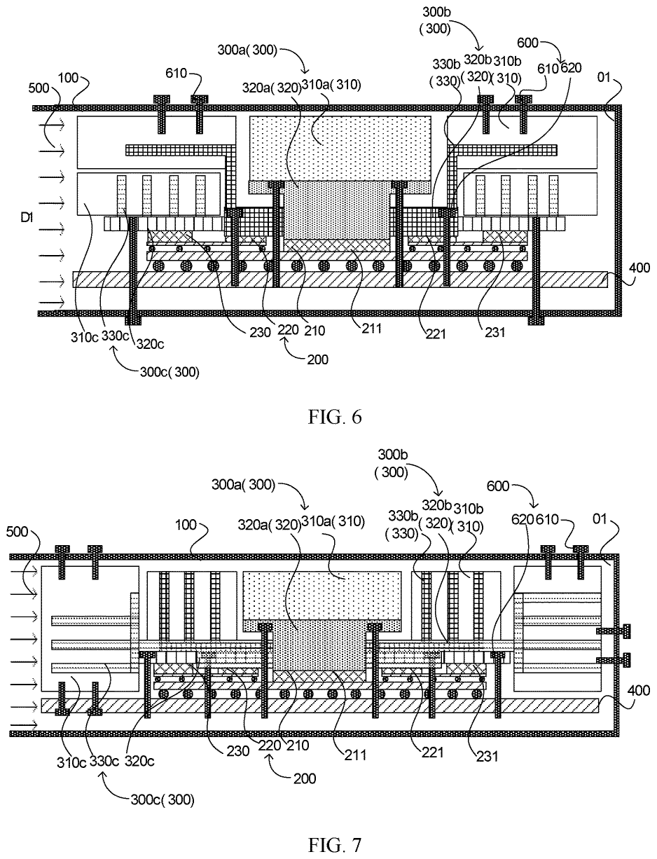

FIG. 6 is a schematic diagram of a structure of the electronic device according to an embodiment of this application. With reference to FIG. 6, the electronic device in this application further includes a circuit board 400, and the heat source 200 is fixedly disposed on the circuit board 400. Each heat source 200 is disposed on a same side surface of the circuit board 400. Certainly, the heat source 200 may also be fixedly disposed on the cavity 100 based on an actual requirement. This is not limited in this application.

FIG. 7 is a schematic diagram of a structure of the electronic device according to an embodiment of this application. With reference to FIG. 6 and FIG. 7 together, the heat dissipation assembly 300 may be fixedly disposed on the circuit board 400, and the heat dissipation assembly 300 may also be fixedly disposed in the cavity 100. Specifically, the heat dissipation assembly 300 may be connected to the circuit board 400 or the cavity 100 through a connecting member 600. As shown in FIG. 6, the second heat sink 310b is fixedly disposed in the cavity 100 by using a first fastener 610. The first fastener 610 may be a screw, a bolt, or the like. In addition, the second substrate 320b is fixedly disposed on the circuit board 400 by using a second fastener 620.

In some optional embodiments, in the at least two heat dissipation assemblies 300, one heat sink 310 is fixedly disposed on a substrate 320 connected to another heat sink 310 to achieve stress coupling. Certainly, each heat dissipation assembly 300 may also be independently fixedly disposed in the cavity 100 or on the circuit board 400 to achieve stress decoupling. It may be understood that the heat dissipation assembly 300 may be fixedly connected to the cavity 100, the circuit board 400, or the substrate 320, or may be floatingly connected, which is specifically set based on an actual situation, as long as good contact between the heat dissipation assembly 300 and the heat source 200 is ensured, thereby reducing thermal resistance during heat transfer and improving heat transfer efficiency. In addition, a fixed position of the heat dissipation assembly 300 is also flexibly set based on an actual situation.

In some optional embodiments, orthographic projections of two substrates 320 corresponding to heat sources 200 with different temperature specifications on the circuit board 400 do not overlap, so that thermal crosstalk between the heat sources 200 with different temperature specifications is avoided.

With continued reference to FIG. 2, FIG. 6, and FIG. 7, the electronic device further includes a heat dissipation air duct 500, and all the heat sources 200 are located on the heat dissipation air duct 500. It may be understood that the cold airflow in the heat dissipation air duct 500 may be a natural wind, or may be an airflow generated by a fan. The fan may be a blower or an exhaust fan. An arrangement position of the fan may be set based on an actual requirement.

A distance between two heat sources 200 with different temperature specifications is less than or equal to a first preset value. The first preset value is designed based on an actual situation, that is, the distance between the two heat sources 200 with different temperature specifications is short, and space is limited.

It should be noted that an airflow direction in the heat dissipation air duct may be parallel to a surface of the circuit board 400 or perpendicular to a surface of the circuit board 400. This is not limited in this application and may be set based on an actual requirement.

In some optional embodiments, the heat sink 310 is located on the heat dissipation air duct 500. Along the airflow direction D1 in the heat dissipation air duct 500, a temperature specification of a heat source 200 corresponding to a heat sink 310 located upstream of the airflow is lower than a temperature specification of a heat source 200 corresponding to a heat sink 310 located downstream of the airflow. As shown in FIG. 2, along the airflow direction D1 in the heat dissipation air duct 500, the third heat sink 310c is located upstream of the first heat sink 310a in the airflow, and the second heat sink 310b is located upstream of the first heat sink 310a in the airflow, so that the third heat sink 310c and the second heat sink 310b can be first in contact with the cold airflow, thereby providing lower temperature specifications for the third heat source 230 and the second heat source 220.

To avoid thermal crosstalk between the first heat sink 310a and the second heat sink 310b, along the gravity direction Dg, the first heat sink 310a is located below the second heat sink 310b. In this way, a convection effect between the first heat sink 310a and the second heat sink 310b in the gravity direction Dg can be enhanced, and heat dissipation efficiency can be improved. In addition, when the airflow direction is perpendicular to the gravity direction Dg, along the airflow direction in the heat dissipation air duct 500, both the second heat sink 310b and the third heat sink 310c can be first in contact with the cold airflow, thereby avoiding thermal crosstalk between the second heat sink 310b and the third heat sink 310c.

Each heat source 200 may include one heating element, or may include two or more heating elements. A corresponding heat dissipation assembly 300 may include one heat sink 310, or may include two or more heat sinks 310, and may be flexibly configured based on the packaging space and a heat dissipation requirement, to balance heat dissipation efficiency and space utilization.

With continued reference to FIG. 2 and FIG. 6, the second heat source 220 includes at least two second heating elements 221 arranged at intervals. Along the airflow direction D1 in the heat dissipation air duct 500, at least one second heating element 221 is located upstream of the first heat source 210 in the airflow. The at least two second heating elements 221 may surround the first heat source 210, or may be disposed on one side of the first heat source 210. This is not specifically limited.

As shown in FIG. 2, the second heat dissipation assembly 300b may include one second heat sink 310b. Two second heating elements 221 may share the second heat sink 310b. Along the airflow direction in the heat dissipation air duct 500, the second heat sink 310b is located upstream of the first heat sink 310a in the airflow.

Alternatively, as shown in FIG. 6, the second heat dissipation assembly 300b includes at least two second heat sinks 310b. The second heat sinks 310b are in a one-to-one correspondence with the second heating elements 221. In this case, each second heat sink 310b may be as close as possible to a corresponding second heating element 221 to shorten a heat conduction distance, thereby improving heat conduction efficiency. The at least two second heat sinks 310b may share one second substrate 320b, or each of the second heat sinks 310b may correspond to an independent second substrate 320b. For example, at least one second heat sink 310b is located upstream of the first heat sink 310a in the airflow.

Certainly, the first heat source 210 may include one first heating element 211, or may include two or more first heating elements 211.

Similarly, the third heat source 230 may include at least two third heating elements 231 arranged at intervals. For a specific arrangement of the third heat dissipation assembly 300c corresponding to the third heat source 230, refer to the arrangement of the second heat dissipation assembly 300b corresponding to the second heat source 220. Details are not described herein again.

In some optional embodiments, the heat sink 310 includes a plurality of heat dissipation fins, and two adjacent heat dissipation fins are arranged at intervals. Along the airflow direction in the heat dissipation air duct, a distance between the heat sources 200 is short, and the heat dissipation fins may extend along a direction perpendicular to the airflow direction in the heat dissipation air duct to increase sizes of the heat dissipation fins or the distance between adjacent heat dissipation fins, so that the heat sink 310 can obtain an optimal air volume to meet heat dissipation requirements of the heat sources 200, thereby reducing a quantity or load of fans, and achieving an energy-saving effect.

It may be understood that the heat dissipation fins may also extend in other directions, as long as the heat dissipation fins can effectively utilize the packaging space or optimize flow resistance of the heat sink 310 to improve heat dissipation efficiency of the heat sink 310.

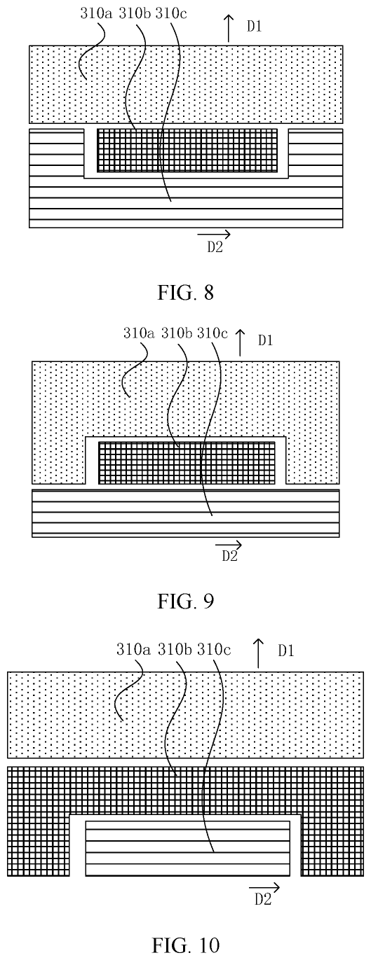

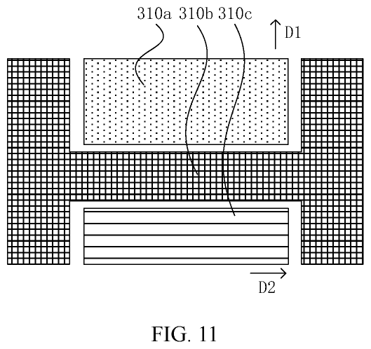

FIG. 8 is a top view of heat dissipation fins of different heat sinks according to an embodiment of this application. FIG. 9 is a top view of heat dissipation fins of different heat sinks according to an embodiment of this application. FIG. 10 is a top view of heat dissipation fins of different heat sinks according to an embodiment of this application. FIG. 11 is a top view of heat dissipation fins of different heat sinks according to an embodiment of this application. With reference to FIG. 8 to FIG. 11 together, a shape, size, and position of each heat sink 310 are set based on an actual requirement. Along the airflow direction D1 in the heat dissipation air duct, each heat sink 310 is stacked separately to fully utilize space.

As shown in FIG. 8 to FIG. 11, a width of the third heat sink 310c in a width direction D2 of the heat sink is less than or equal to a width of the first heat sink 310a in the width direction D2.

As shown in FIG. 11, a width of the second heat sink 310b in the width direction D2 is greater than the width of the first heat sink 310a in the width direction D2 and/or the width of the third heat sink 310c in the width direction D2.

In some optional embodiments, orthographic projections of the heat sinks 310 on the circuit board 400 do not overlap, to avoid thermal crosstalk between the heat sinks 310 and improve the heat dissipation effect.

It is clear that a person skilled in the art can make various modifications and variations to embodiments of this application without departing from the spirit and scope of this application. Therefore, this application is intended to include these modifications and variations provided that these modifications and variations of this application fall within the scope of the claims of this application and equivalent technologies thereof.

What is claimed is:

1. An electronic device, comprising:
a cavity;
a heat dissipation air duct, disposed in the cavity and allowing an airflow to pass through to take away heat in the cavity;
a first heat source, disposed in the cavity;
a third heat source, disposed in the cavity, wherein a temperature specification of the third heat source is lower than a temperature specification of the first heat source;
a first heat dissipation assembly, located in the heat dissipation air duct and in thermal contact with the first heat source; and
a third heat dissipation assembly, located in the heat dissipation air duct and in thermal contact with the third heat source, wherein
the third heat dissipation assembly is isolated from the first heat dissipation assembly, and the third heat dissipation assembly is located upstream of an airflow direction of the airflow relative to the first heat dissipation assembly.

2. The electronic device according to claim 1, wherein the first heat dissipation assembly comprises a first heat sink, and the third heat dissipation assembly comprises a third heat sink, wherein along a gravity direction, a height of a top surface of the third heat sink relative to a bottom plate of the cavity is lower than a height of a top surface of the first heat sink relative to the bottom plate of the cavity.

3. The electronic device according to claim 2, wherein the first heat sink comprises a plurality of first heat dissipation fins.

4. The electronic device according to claim 2, wherein the third heat sink comprises a plurality of third heat dissipation fins.

5. The electronic device according to claim 2 wherein the first heat dissipation assembly further comprises a first substrate, wherein the first substrate is disposed between the first heat source and the first heat sink and is in thermal contact with the first heat source and the first heat sink, respectively.

6. The electronic device according to claim 2, wherein the third heat dissipation assembly further comprises a third substrate, wherein the third substrate is disposed between the third heat source and the third heat sink and is in thermal contact with the third heat source and the third heat sink, respectively.

7. The electronic device according to claim 6, wherein the third heat dissipation assembly further comprises a third heat-conducting member, wherein the third heat-conducting member is disposed between the third substrate and the third heat sink and is in thermal contact with the third substrate and the third heat sink, respectively.

8. The electronic device according to claim 2, wherein a circuit board is disposed in the cavity, and the first heat source and the third heat source are fixedly disposed on the circuit board.

9. The electronic device according to claim 8, wherein orthographic projections of the first heat sink and the third heat sink on the circuit board do not overlap with each other.

10. The electronic device according to claim 1, wherein the electronic device further comprises a second heat source disposed in the cavity and a second heat dissipation assembly in thermal contact with the second heat source, wherein the second heat dissipation assembly is disposed in the heat dissipation air duct and located between the first heat dissipation assembly and the third heat dissipation assembly in the airflow direction.

11. The electronic device according to claim 10, wherein a temperature specification of the second heat source is lower than the temperature specification of the first heat source and higher than the temperature specification of the third heat source, and the second heat dissipation assembly is isolated from the first heat dissipation assembly and the third heat dissipation assembly, respectively.

12. The electronic device according to claim 10, wherein the second heat dissipation assembly further comprises a second heat sink, and the third heat dissipation assembly further comprises a third substrate and a third heat sink, wherein the third substrate is disposed between the third heat source and the third heat sink and is in thermal contact with the third heat source and the third heat sink, respectively, and is in thermal contact with the second heat source and the second heat sink, respectively.

13. The electronic device according to claim 10, wherein the second heat dissipation assembly further comprises a second heat sink and a second heat dissipation substrate, wherein the second heat dissipation substrate is disposed between the second heat source and the second heat sink and is in thermal contact with the second heat source and the second heat sink, respectively.

14. The electronic device according to claim 10, wherein a distance between the second heat source and the first heat source and a distance between the second heat source and the third heat source are less than or equal to a first preset value.

15. The electronic device according to claim 10, wherein the first heat dissipation assembly comprises a first heat sink, the second heat dissipation assembly comprises a second heat sink, and the third heat dissipation assembly comprises a third heat sink, wherein orthographic projections of the first heat sink, the second heat sink, and the third heat sink on a circuit board on which the first heat source is packaged do not overlap with each other.

16. The electronic device according to claim 14, wherein a height of the third heat sink in a gravity direction relative to a bottom plate of the cavity is greater than a height of the second heat sink in the gravity direction relative to the bottom plate of the cavity or a height of the first heat sink in the gravity direction relative to the bottom plate of the cavity.

17. The electronic device according to claim 10, wherein the first heat dissipation assembly comprises a first heat sink, the second heat dissipation assembly comprises a second heat sink, and the third heat dissipation assembly comprises a third heat sink, wherein a width of the third heat sink in a width direction is less than or equal to a width of the first heat sink in the width direction.

18. The electronic device according to claim 17, wherein a width of the second heat sink in the width direction is greater than the width of the first heat sink in the width direction and/or the width of the third heat sink in the width direction.
